(19) United States
(12) Patent Application Publication
(10) Pub. No.: US 2008/0237728 A1
(43) Pub. Date: Oct. 2, 2008

(54) Semiconductor device and method for manufacturing the same

(76) Inventors: Riichiro Mitsuhashi, Leuven (BE); Kota Oikawa, Leuven (BE); Osullivan Barry, Leuven (BE); Stefan Kubicek, Pellenberg (BE)

Correspondence Address: MCDERMOTT WILL & EMERY LLP, 600 13TH STREET, NW, WASHINGTON, DC, 20005-3096, US

(21) Appl. No.: 11/976,964

(22) Filed: Oct. 30, 2007

(30) Foreign Application Priority Data
Mar. 30, 2007 (JP) 2007-093284

(51) Int. Cl. H01L 27/092; H01L 21/3205

(52) U.S. Cl. 257/369; 438/585; 257/E27.062; 257/E21.294

(57) ABSTRACT

A semiconductor device includes: a p-type active region and an n-type active region which are formed in a semiconductor substrate; a first MISFET including a first gate insulating film formed on the p-type active region and a first gate electrode formed on the first gate insulating film and including a first electrode formation film containing a metal element; and a second MISFET including a second gate insulating film formed on the n-type active region and a second gate electrode formed on the second gate insulating film and including a second electrode formation film. The second electrode formation film contains the same metal element as the first electrode formation film and has an oxygen content higher than the first electrode formation film.

### BACKGROUND OF THE INVENTION

1. Field of the Invention

The present invention relates to semiconductor devices, such as MISFETs and manufacturing methods thereof.

2. Related Art

In recent years, semiconductor devices are being required to operate at high speed with low power consumption. In order to achieve high speed operation of the semiconductor devices, the gate capacitance of MISFETs (Metal Insulator Semiconductor Field Effect Transistors) is increased to increase the driving current. In order to increase the gate capacitance, the distance between electrodes (between a substrate and an electrode) must be reduced by reducing the thickness of the gate insulating films. In response to this demand, the physical thickness of the gate insulating films of the MISFETs are reduced now to approximately 2 nm in a case using SiON (silicon oxinitride). While, recent reduction in thickness of the gate insulating films involves a problem of gate leak current. In order to cope with this problem, the use of materials having high dielectric constants, such as an oxide containing Hf is being examined in place of the conventionally used silicon oxide (SiO₂) based materials.

Reduction in thickness of the gate insulating films involves another problem that the gate electrodes that have been made of polysilicon are depleted to lower the gate capacitance. In terms of a film thickness of a gate insulating film made of, for example, silicon oxide (SiO₂), the lowered amount of the gate capacitance in this case increases the film thickness by approximately 0.5 nm. The thinned gate insulating films inevitably involve an increase in gate leak current, but nevertheless reduction in effective thickness of the gate insulating films can be achieved without increasing the gate leak current if depletion can be suppressed. When the thickness of a SiO₂ film is reduced by 0.1 nm, leak current increases ten times or more than that before reduction in thickness. Thus, suppression of depletion of the gate electrodes is significantly effective.

In view of the foregoing, exchange of the material of the gate electrodes from polysilicon to metal causing no depletion is being examined for obviating depletion of the gate electrodes. Nevertheless, while formation of the impurity level by implantation of impurity into polysilicon enables separate formation of a p-type MISFET electrode and an n-type MISFET electrode, such separate formation is disabled with the metal.

Besides, recent semiconductor devices are required to operate at further higher speed. Therefore, lowering of threshold voltage (Vt) is an essential issue, and the p-type MISFET electrode and the n-type MISFET electrode should have work functions (WF) approximating to the band edge of silicon. Wherein, the band edge means a high WF approximating to the work function (approximately 5.2 eV) at the upper part (top edge) of the valence band of silicon in the p-side region and a low WF approximating to the work function (approximately 4.1 eV) at the bottom part (bottom edge) of the conduction band of silicon in the n-side region. The conventional semiconductor devices are so designed that the p-type MISFET and the n-type MISFET thereof have the same threshold voltage Vt by using metal having a WF corresponding to the substantial mean value between the WF in the p-side region and that in the n-side region as a common material of the p-type MISFET electrode and the n-type MISFET electrode. Such semiconductor devices will become impractical any longer.

Under the above circumstances, search for suitable metal materials for the p-type MISFET electrode and the n-type MISFET electrode are being promoted recently. No suitable metal material has been found yet because any materials having appropriate WFs at normal temperature vary in WF when they undergo high-temperature treatment, such as a source/drain regions activating step and the like, but at last, several potential candidates are found recently. Ta-based materials, such as TaC, TaN, and the like are now examined as potential candidates of the material for the n-type MISFET electrodes, as indicated in W. J. Taylor Jr., IEDM, 2006, page 625 and P. D. Kirsch, IEDM, 2006, page 629. Favorable characteristics are exhibited in a combination of a gate electrode made of a Ta-based material and a gate insulting film made of a lanthanoide-based material, such as La or the like.

On the other hand, as potential candidates as materials for the p-type MISFET electrode, noble metal, such as Pt, Ir, and the like, MoO (molybdenum oxide), and the like are proposed in C. H. Wu, IEDM, 2006, page 617 and R. Singanamalla, IEDM 2006, page 637.

In the case where the material and the compositions of the gate electrodes are different between the p-type MISFET and the n-type MISFET, formation of the p-type MISFET and the n-type MISFET on a single semiconductor substrate, for example, formation of a CMIS (Complementary Metal Insulator Semiconductor) requires a process of, for example: depositing a metal for the n-type MISFET (or the p-type MISFET) on a gate insulating film; selectively removing a part of the metal for the n-type MISFET (or the p-type MISFET) which is formed in the p-type MISFET region (or the n-type MISFET region); and then, depositing a meal for the p-type MISFET (or the n-type MISFET) on a part of the gate insulating film which is formed in the p-type MISFET region (or the n-type MISFET region), as disclosed in F. Ootsuka et al., “Extended Abstract of the 2006 International Conference on Solid State Device and Materials,” Yokohama, 2006, pp. 1116-1117.

### SUMMARY OF THE INVENTION

Most of all the above potential candidates of the material for the electrodes, however, are different in element and composition between the p-type MISFET and the n-type MISFET. In this case, employment of the above CMIS formation method requires simultaneous formation of patterns for the gate electrodes in the p-type MISFET region and the n-type MISFET region. In general, the patterns of the gate electrodes are formed by dry etching after photolithography. While, recent miniaturization of semiconductor devices results in gate lengths of 50 nm or smaller, whereby a recessed amount of polysilicon substrates after etched must be several nanometers or smaller. In the case where the elements and the compositions of the electrodes are significantly different between the p-type MISFET electrode and the n-type MISFET, it is too difficult to equalize the etching rates of the electrodes in dry etching to satisfy the aforementioned requisites for miniaturization. Further, the significant difference in element and composition may make the characteristics of the gate electrodes, such as thermal stability of the gate electrodes, stress on the gate insulating films, reactivity with the gate insulating films, and the like to be different therebetween significantly. Thus, CMIS formation might be impractical.

As materials having WFs suitable for the n-type MISFET region, TaC or TaN with a cap layer made of LaO are examined. These materials can be handled comparatively easily and can be readily used in semiconductor manufacture lines. On the other hand, as materials having WFs suitable for the p-type MISFET region, noble metal materials, such as Ru, Pt, and the like have been proposed, which might be difficult for use when taking problems of pollution into consideration.

Furthermore, the aforementioned CMIS formation method requires removal of the material of the metal-made gate electrode immediately on the gate insulating film, thereby inviting change in film thickness of the gate insulating film and reliability lowering, as disclosed in F. Ootsuka et al., “Extended Abstract of the 2006 International Conference on Solid State Device and Materials,” Yokohama, 2006. Although several other processes for separately forming the p-type MISFET and the n-type MISFET may be contemplated, removal of a film formed on the gate insulating film might inevitably invite damage to the thinned gate insulating film.

In view of the foregoing, the present invention has its object of providing a semiconductor device including a metal gate electrode having a suitable work function, which is capable of high-speed operation with depletion suppressed and a manufacturing method thereof.

In order to achieve the above object, a semiconductor device in accordance with the present invention includes: a semiconductor substrate; a p-type active region and an n-type active region which are formed in the semiconductor substrate; a first MISFET including a first gate insulating film formed on the p-type active region and a first gate electrode formed on the first gate insulating film and including a first electrode formation film containing a metal element; and a second MISFET including a second gate insulating film formed on the n-type active region and a second gate electrode formed on the second gate insulating film and including a second electrode formation film containing the metal element and having an oxygen content higher than the first electrode formation film.

In the above arrangement, the first gate electrode and the second gate electrode formed on the single semiconductor substrate are made of different materials, and the electrode formation films composing the respective gate electrodes contain the same metal element. Further, the oxygen content of the second electrode formation film is higher than that of the first electrode formation film. In this case, when a material having a low work function, such as TaC or the like is used as the material of the first electrode formation film while a material having a high work function, such as TaCO or the like is used as the material of the second electrode formation film, an n-type MISFET and a p-type MISFET including gate electrodes having appropriate work functions approximating to the band edge of silicon can be formed. As a result, a semiconductor device, such as a CMIS can be attained which has high threshold voltage and capable of high-speed operation with depletion of the gate electrodes suppressed even when miniaturized.

Herein, description will be given with reference to FIG. 1 to the reason why materials containing the same metal element and having oxygen contents different from each other are used as the materials of the first electrode formation film and the second electrode formation film.

FIG. 1 is a table indicating materials for a gate electrode and work functions thereof in the present invention. FIG. 1 proves that TaCO has a work function (WF) considerably higher than TaN when TaCO (Ta:C:O=45:45:10, for example) is used as the material of the gate electrode. Referring to TaC, with no intermediate layer for anti-oxidation provided, high-temperature annealing oxidizes TaC to increase the work function thereof. From the foregoing, it is cleared that the WF varies according to a rate of oxygen contained in the material of an electrode. Further, TaCO has a high work function irrespective of a kind of the gate insulating film, which means that the work function of TaCO might be less dependent on the gate insulating film. Metal films containing Ta, C, or O have been used in the conventional semiconductor devices and are materials easily handled as the materials for the p-type MISFET electrode.

While, as also indicated in FIG. 1, in the case where TaC is use, change in kind of the gate insulating film by, for example, providing a cap layer made of LaO on a HfSiON film can further reduce the work function. Therefore, TaC might be useful as a material of the n-type MISFET electrode.

In view of the aforementioned knowledge, it is cleared that when TaC is used as a material of the n-type MISFET electrode while TaCO is used as a material of the p-type MISFET, a CMIS can be formed which has rather low threshold voltage (which varies in proportion to the work function) and exhibits favorable characteristics. Since TaC and TaCO are the same in element other than oxygen, the same characteristics, such as the etching rate as etching characteristics and other physical characteristics might be exhibited. In consequence, the respective electrode materials can be etched simultaneously in forming the gate electrodes to suppress complication of a CMIS manufacturing process unlike the conventional CMIS manufacturing method.

It is noted that, as described above, the work function of TaC can be lowered further by using a gate insulating film containing La. There is apprehension that the use of a gate insulating film containing La in the p-type MISFET may invite lowering of the work function of the p-type MISFET electrode. In the case of TaCO, however, the use of the gate insulating film containing La hardly lowers the work function of the gate electrode, as indicated in FIG. 1. Thus, the use of TaC and TaCO as the materials of the respective gate electrodes can achieve respective appropriate work functions even with the use of a gate insulating film made of HfO₂, HfSiO, HfSiON, or any of them containing La.

It was additionally found that when a gate electrode of which main material contains Ta other than TaC, such as TaN, TaLaN, or the like is used as the n-type MISFET gate electrode, the use of TaCO as the material of the p-type MISFET facilitates the processing, such as etching of the gate electrodes when compared with the conventional semiconductor device manufacturing method in which a noble metal or the like is used as the material of the p-type MISFET electrode. This might be because of an effect achieved by adding oxygen to Ta. Consequently, even when an oxide which exhibits metal characteristics and contains Ta, such as TaNO having a comparatively low oxygen content, is used rather than TaCO as a material of the p-type MISFET electrode, a high work function substantially equal to that of TaCO can be achieved.

According to the result of the above study, a semiconductor device in accordance with the present invention includes a first electrode formation film containing a metal and a second electrode formation film which contains the same metal as the first electrode formation film and has an oxygen content higher than the first electrode formation film.

A semiconductor device manufacturing method in accordance with the present invention is a method for manufacturing a semiconductor device including a semiconductor substrate, a p-type active region, an n-type active region, a first MISFET including a first gate insulating film and a first gate electrode, and a second MISFET including a second gate insulating film and a second gate electrode, wherein the method includes the steps of: (a) forming a gate insulating film on the semiconductor substrate after the p-type active region and the n-type active region are formed in the semiconductor substrate; (b) forming a first electrode formation film on a part of the gate insulating film which is located on the p-type active region, the first electrode formation film containing a metal element; (c) forming a second electrode formation film on a part of the gate insulating film which is located on the n-type active region, the second electrode formation film containing the metal element and having an oxygen content higher than the first electrode formation film; and (d) removing a part of the first electrode formation film, a part of the second electrode formation film, and a part of the gate insulating film to form on the p-type active region the first gate electrode provided on the first gate insulating film and including the first electrode formation film and form on the n-type active region the second gate electrode provided on the second gate insulating film and including the second electrode formation film. Wherein, the step (b) may include the steps of: (b1) forming the first electrode formation film on each of the parts of the gate insulating film which are located on the p-type active region and the n-type active region; and (b2) removing the first electrode formation film with the part located on the p-type active region left, and the step (c) may include the steps of: (c1) forming the second electrode formation film on the first electrode formation film and the gate insulating film; and (c2) removing the second electrode formation film with the part located on the n-type active region left.

In the above method, the materials used as the materials of the first electrode formation film and the second electrode formation film contain the same meal element and have oxygen contents different from each other, and therefore, these materials have similar characteristics, such as etching characteristics and other physical characteristics.

Accordingly, in the semiconductor device manufacturing method in accordance with the present invention, the first electrode formation film and the second electrode formation film can be etched comparatively easily in patterning the first gate electrode and the second gate electrode in the predetermined regions in the step (d). Further, change in oxygen content changes the work functions of the first electrode formation film and the second electrode formation film, thereby achieving simultaneous formation of the first MISFET and the second MISFET having conductivity types different from each other in the single semiconductor substrate.

Furthermore, in the semiconductor device manufacturing method in accordance with the present invention, the step (b) may include the step of forming the first electrode formation film on each of the parts of the gate insulating film which are located on the p-type active region and the n-type active region, and the step (c) may include the step of oxidizing a part of the first electrode formation film which is located on the n-type active region to form the second electrode formation film containing the metal element and having an oxygen content higher than the first electrode formation film. Wherein, in the step (c), the part of the first electrode formation film which is located on the n-type active region may be oxidized by performing thermal treatment under an oxygen atmosphere.

In the above method, the second electrode formation film is formed by oxidizing the first electrode formation film by thermal treatment in the step (c). Formation of the second electrode formation film formed thereby eliminates the need to remove the first electrode formation film immediately on the gate electrode to suppress damage to the gate insulating film and change in film thickness of the gate insulating film in a dry etching process and the like. As a result, employment of the semiconductor device manufacturing method in accordance with the present invention achieves manufacture of a highly reliable semiconductor device even when miniaturized.

In addition, in the step (c), the part of the first electrode formation film which is located on the n-type active region may be oxidized by injecting an oxygen ion. This method achieves formation of the second electrode formation film likewise the above described oxidation by thermal treatment with no damage to the gate insulating film invited, achieving comparatively easy manufacture of a highly reliable semiconductor device.

### BRIEF DESCRIPTION OF THE DRAWINGS

FIG. 1 is a table indicating materials for gate electrodes and work functions in accordance with the present invention.

FIG. 2A to FIG. 2E are sectional views showing respective steps of a semiconductor device manufacturing method in accordance with Embodiment 1 of the present invention.

FIG. 3A to FIG. 3E are sectional views showing respective steps of the semiconductor device manufacturing method in accordance with Embodiment 1.

FIG. 4A to FIG. 4D are sectional views showing respective steps of the semiconductor device manufacturing method in accordance with Embodiment 1.

FIG. 5A to FIG. 5E are sectional views showing respective steps of a semiconductor device manufacturing method in accordance with Embodiment 2 of the present invention.

FIG. 6A to FIG. 6E are sectional views showing respective steps of the semiconductor device manufacturing method in accordance with Embodiment 2.

FIG. 7 is a sectional view showing a step of the semiconductor device manufacturing method in accordance with Embodiment 2.

FIG. 8A to FIG. 8D are sectional views showing respective steps of a semiconductor device manufacturing method in accordance with Embodiment 3 of the present invention.

FIG. 9A to FIG. 9D are sectional views showing respective steps of the semiconductor device manufacturing method in accordance with Embodiment 3.

FIG. 10 is a sectional view showing a step of the semiconductor device manufacturing method in accordance with Embodiment 3.

### DESCRIPTION OF PREFERRED EMBODIMENTS

### Embodiment 1

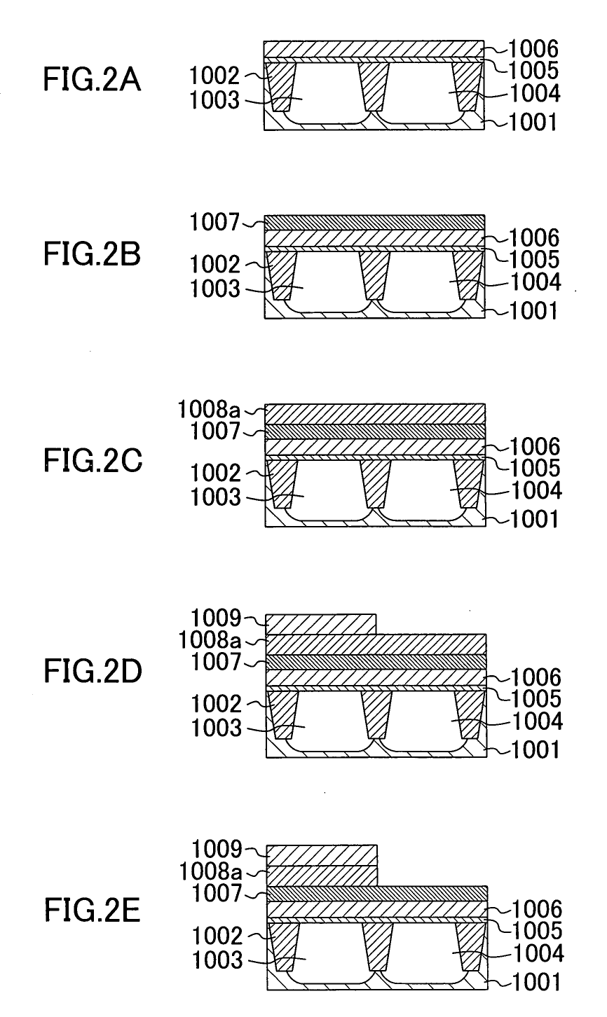

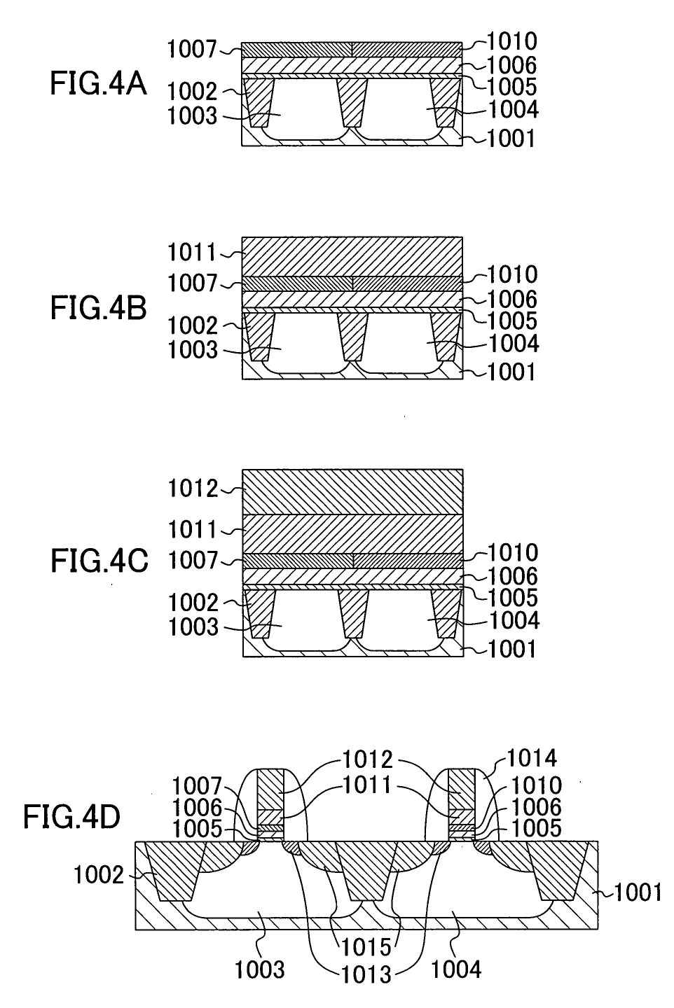

A semiconductor device and a method for manufacturing it in accordance with Embodiment 1 of the present invention will be described below with reference to the drawings. FIG. 2 to FIG. 4 are sectional views showing respective steps of the semiconductor device manufacturing method in accordance with the present embodiment. First of all, a structure of the semiconductor device in accordance with the present embodiment will be described with reference to FIG. 4D.

As shown in FIG. 4D, the semiconductor device in accordance with the present embodiment includes: a semiconductor substrate 1001 made of, for example, silicon; a p-type active region 1003 and an n-type active region 1004 formed in the semiconductor substrate 1001; an isolation layer 1002 for isolating the p-type active region 1003 and the n-type active region 1004; and source/drain regions 1015 and extension regions 1013 formed in the p-type active region 1003 and the n-type active region 1004.

Further, the semiconductor device of the present embodiment includes an underlying film 1005, a gate insulating film 1006, a first electrode formation film 1007, an intermediate film 1011, and a third electrode formation film 1012. The underlying film 1005, which is made of SiO₂ or the like, is formed on a region of the semiconductor substrate 1001 which is located between two adjacent extension regions 1013 in the p-type active region 1003 as viewed in plan. The gate insulating film 1006, which is made of HfSiON or the like, is formed on the underlying film 1005. The first electrode formation film 1007, which is made of TaC or the like, is formed on the gate insulating film 1006. The intermediate film 1011, which is made of TaN or the like, is formed on the first electrode formation film 1007. The third electrode formation film 1012, which is made of polysilicon or the like, is formed on the intermediate film 1011. In other words, in the p-type active region 1003 of the semiconductor substrate 1001, an n-type MISFET is formed which is composed of the underlying film 1005, the gate insulating film 1006, a first gate electrode including the first electrode formation film 1007, the intermediate film 1011, and the third electrode formation film 1012, the source/drain regions 1015, and the extension regions 1013.

As well, the semiconductor device of the present embodiment includes, in the n-type active region 1004 of the semiconductor substrate 1001, the underlying film 1005, the gate insulating film 1006, a second electrode formation film 1010, the intermediate film 1011, and the third electrode formation film 1012. The underlying film 1005, which is made of SiO₂ or the like, is formed on a region of the semiconductor substrate 1001 which is located between two adjacent extension regions 1013 in the n-type active region 1004 as viewed in plan. The gate insulating film 1006, which is made of HfSiON or the like, is formed on the underlying film 1005. The second electrode formation film 1010, which is made of TaCO or the like, is formed on the gate insulating film 1006. The intermediate film 1011, which is made of TaN or the like, is formed on the second electrode formation film 1010. The third electrode formation film 1012, which is made of polysilicon or the like, is formed on the intermediate film 1011. In other words, in the n-type active region 1004 of the semiconductor substrate 1001, a p-type MISFET is formed which is composed of the underlying film 1005, the gate insulating film 1006, a second gate electrode including the second electrode formation film 1010, the intermediate film 1011, and the third electrode formation film 1012, the source/drain regions 1015, and the extension regions 1013.

Sidewalls 1014 as composition members of the respective MISFETs are formed on the side faces of the underlying film 1005, the gate insulating film 1006, and the first gate electrode and on the side faces of the underlying film 1005, the gate insulating film 1006, and the second gate electrode.

In the semiconductor device of the present embodiment, the first gate electrode and the second gate electrode formed on the single semiconductor substrate 1001 are made of materials different from each other and are formed of the electrode formation films containing the same metal element (Ta). Further, the oxygen content of the second electrode formation film 1010 composing the second gate electrode is larger than that of the first gate electrode formation film 1007 composing the first gate electrode. According to the above arrangement, namely, when TaC having a low work function is used as the material of the first electrode formation film 1007 while TaCO having a high work function is used as the material of the second electrode formation film 1010, a semiconductor device can be attained which includes an n-type MISFET and a p-type MISFET including the gate electrodes made of materials of which work functions are comparatively close to the band edge of silicon. As a result, a semiconductor device such as a CMIS having low threshold voltage and capable of high-speed operation with depletion of the gate electrodes suppressed can be attained even when miniaturized.

Further, in the semiconductor device of the present embodiment, the third electrode formation film 1012 is formed on the first gate electrode and the second gate electrode which are formed in the n-type MISFET and the p-type MISFET, respectively, thereby contemplating lowering of the resistances of the first gate electrode and the second gate electrode.

In the semiconductor device of the present embodiment, the intermediate film 1011 is provided between the first electrode formation film 1007 and the third electrode formation film 1012 and between the second electrode formation film 1010 and the third electrode formation film 1012. Even if the first electrode formation film 1007 is made of a material which is liable to be oxidize, the intermediate film 1011 made of TaN or the like serves as an anti-oxidation film.

The semiconductor device manufacturing method in accordance with the present embodiment will be described next with reference to FIG. 2 to FIG. 4.

First, as shown in FIG. 2A, the p-type active region 1003, the n-type active region 1004, and the isolation layer 1002 for separating them are formed in the semiconductor substrate 1001. RTO (Rapid Thermal Oxidation) using an oxygen gas is performed to deposit the underlying layer 1005 made of, for example, SiO₂ and having a film thickness of approximately 1 nm on the semiconductor substrate 1001. Any suitable gas other than the oxygen gas may be used. Thermal treatment using a heating furnace may be performed. The material of the underlying film 1005 may be SiON, a chemical oxide, or the like. Then, a HFSiO film having, for example, a high dielectric constant and a thickness of 2.5 nm is deposited by MOCVD (Metal Organic Chemical Vapor Deposition), and the thus deposited HfSiO film is plasma-nitrided to form the gate insulating film 1006 formed of a HfSiON film. The gate insulating film 1006 may be made of HfO₂ or HfSi, or may be formed of any other suitable Hf-based insulating film containing La. Alternatively, any suitable high dielectric, such as Al₂O₃, ZrO₂, LaO, DyO, ScO, or the like may be used, or the gate insulating film 1006 may be made of SiO₂ or SiON other than the high dielectrics according to needs. Rather than MOCVD, CVD (Chemical Vapor Deposition), PVD (Physical Vapor Deposition) or the like may be performed.

Next, as shown in FIG. 2B, the first electrode formation film 1007 made of TaC or the like is deposited on the gate insulating film 1006. As the material of the first electrode formation film 1007, TaLaO, TaN, or the like may be used, wherein a metal material containing Ta is more preferable. The film thickness of the first electrode formation film 1007, which can be changed according to the kind of a material of the first electrode formation film 1007 and the peripheral process, is preferably 10 nm or smaller.

Subsequently, as shown in FIG. 2C, a hard mask 1008a made of SiO₂ or the like is formed on the protection film 1007. Then, a resist 1009 is formed on the hard mask 1008a, and a part of the resist 1009 which is located above the n-type active region 1004 is removed by photolithography, as shown in FIG. 2D.

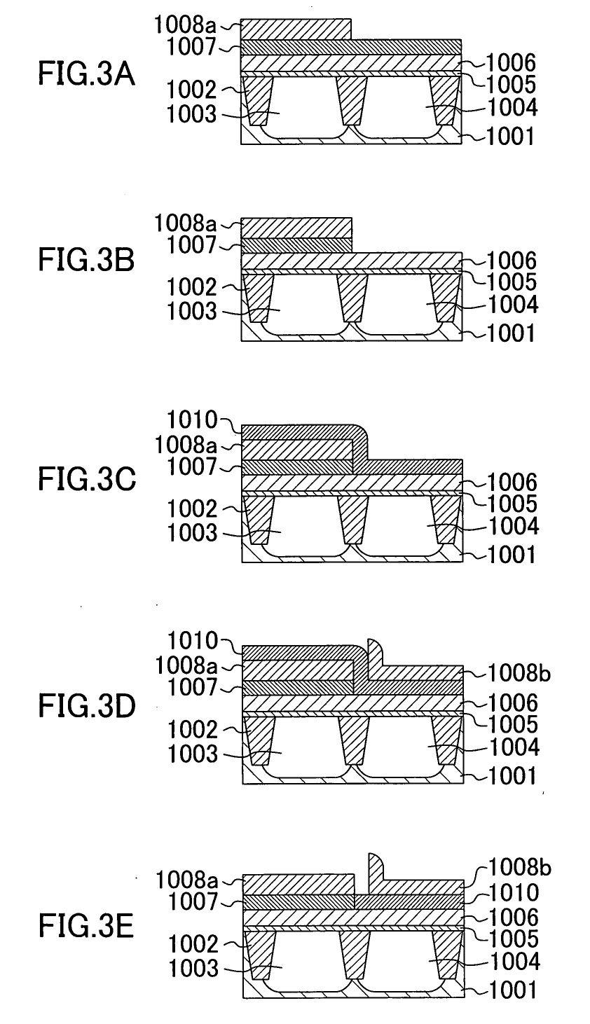

Thereafter, as shown in FIG. 2E, etching using the resist 1009 remaining above the p-type active region 1003 as a mask is performed to remove a part of the hard mask 1008a which is located above the n-type active region 1004. Then, as shown in FIG. 3A, the resist 1009 is removed by ashing to thus leave selectively a part of the hard mask 1008a which is located above the p-type active region 1003.

Next, as shown in FIG. 3B, etching using the hard mask 1008a remaining above the p-type active region 1003 as a mask is performed to remove a part of the first electrode formation film 1007 which is located above the n-type active region 1004.

Subsequently, as shown in FIG. 3C, the second electrode formation film 1010 made of TaCO or the like and having a thickness of 10 nm is deposited on the first electrode formation film 1007 and the hard mask 1008a. Other than TaCO, the material of the second electrode formation film 1010 may be an oxide of the first electrode formation film 1007 or an oxide of a material containing the same element as that of the first electrode formation film 1007, such as TaLaNO, TaNO, or the like. The film thickness of the second electrode formation film 1010, which can be changed according to the kind of a material of the second electrode formation film 1010 and the peripheral process, is preferably 5 nm or smaller.

Thereafter, a hard mask 1008b made of, for example, SiO₂ is formed on the second electrode formation film 1010. Then, a part of the hard mask 1008b which is located above the p-type active region 1003 is removed by photolithography, as shown in FIG. 3D.

Next, as shown in FIG. 3E, the second electrode formation film 1010 is removed by dry etching or the like using the hard mask 1008b formed above the n-type active region 1004 as a mask. Then, the hard masks 1008a and 1008b are removed with the use of hydrofluoric acid or the like, as shown in FIG. 4A. Thus, the first electrode formation film 1007 and the second electrode formation film 1010 are formed above the p-type active region 1003 and the n-type active region 1004, respectively.

Subsequently, as shown in FIG. 4B, the intermediate film 1011, for example, made of TaN or the like and having a thickness of 5 nm is deposited on the first electrode formation film 1007 and the second electrode formation film 1010. The material of the intermediate film 1011 is not limited to TaN, and any other suitable material may be used. In the semiconductor device manufacturing method in the present embodiment, TaC, which is liable to be oxidized at the interface thereof, is used as the material of the first electrode formation film 1007, and therefore, the intermediate film 1011 is provided as an anti-oxidation film. Accordingly, in the case where a less oxidized material, such as TaN or the like is used as the material of the first electrode formation film 1007, the intermediate film 1011 may not be provided.

Thereafter, as shown in FIG. 4C, the third electrode formation film 1012, for example, made of polysilicon and having a thickness of 100 nm is deposited on the intermediate film 1011, and then, an impurity is implanted into the third electrode formation film 1012.

Next, as shown in FIG. 4D, the underlying film 1005, the gate insulating film 1006, the first electrode formation film 1007, the second electrode formation film 1010, the intermediate film 1011, and the third electrode formation film 1012 are etched by photolithography and RIE (Reactive Ion Etching) so that parts of each of them are left on predetermined regions of the p-type active region 1003 and the n-type active region 1004. Then, the extension regions 1013, the sidewalls 1014, the source/drain regions 1015 are formed, and the impurity implanted in the source/drain regions 1015 are activated to thus form the n-type MISFET and the p-type MISFET in the p-type active region 1003 and the n-type active region 1004, respectively. In order to activate the impurity in the source/drain regions 1015, spike annealing at a temperature of, for example, 1050° C. is performed.

By the above method, the n-type MISFET is formed in the p-type active region 1003, wherein the n-type MISFET includes the underlying film 1005, the gate insulating film 1006, the first gate electrode composed of the first electrode formation film 1007, the intermediate film 1011, and the third electrode film 1012, the sidewalls 1014, the source/drain regions 1015, and the extension regions 1013. While in the n-type active region 1004, the p-type MISFET is formed which includes the underlying film 1005, the gate insulating film 1006, the second gate electrode composed of the second electrode formation film 1010, the intermediate film 1011, and the third electrode film 1012, the sidewalls 1014, the source/drain regions 1015, and the extension regions 1013.

In the semiconductor device manufacturing method of the present embodiment, the material (TaC) of the first electrode formation film 1007 and that (TaCo) of the second electrode formation film 1010 contain the same metal element (Ta) and have oxygen contents different from each other. The materials, which contain the same material other than oxygen, might exhibit the same characteristics, such as the etching characteristics and other physical characteristics. Hence, according to the semiconductor device manufacturing method of the present embodiment, the first electrode formation film 1007 and the second electrode formation film 1010 can be etched comparatively easily in patterning the gate electrodes in the predetermined regions in the step shown in FIG. 4D, thereby achieving simultaneous formation of the p-type MISFET and the n-type MISFET on the semiconductor substrate 1001.

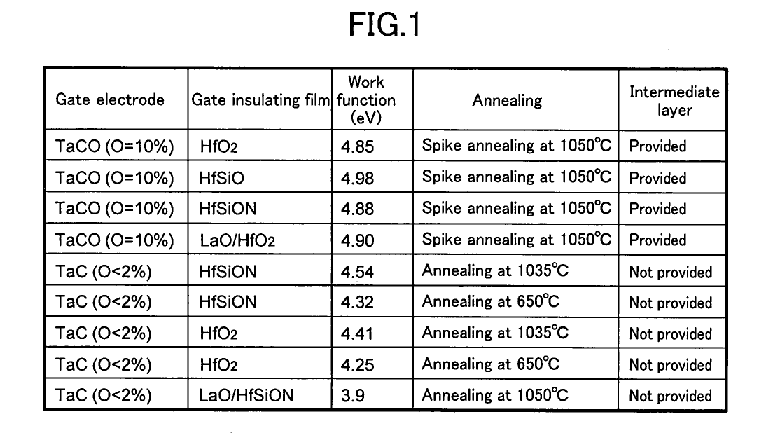

The gate insulating film 1006 is made of HfSiON as one example in the semiconductor device manufacturing method of the present embodiment. While, TaCO used as the material of the gate electrode of the p-type MISFET exhibits a high work function irrespective of the kind of a gate insulating film with less variation in WF with respect to the gate insulating film, as described above (see FIG. 1). In the case using TaCO and TaC as the first and second electrode formation films 1007, 1010, respectively, the gate electrode of the p-type MISFET and the gate electrode of the n-type MISFET can exhibit favorable WFs even when a HfO₂ film with a LaO-made cape layer, HfO₂ film, or any other insulating film is used as the gate insulating film 1006. Further, the first electrode formation film 1007 may be made of any other suitable material which contains the same element as the second electrode formation film 1010 (TaCO), which is easily processed, for example, by etching, and which has a low WF, such as TaN, TaC, or the like.

It is noted that in the semiconductor device and the manufacturing method thereof of the present embodiment, the oxygen content of the first electrode formation film 1007 is preferably 2% or lower. It is also preferable to set the oxygen content of the second electrode formation film 1010 between 10% and 30%, both inclusive because a sufficient WF increasing effect in the presence of oxygen can be achieved while an increase in resistance of the second electrode formation film 1010 can be suppressed. In addition, etching and the like for forming the gate electrodes by processing the first electrode formation film 1007 and the second electrode formation film 1010 can be done comparatively easily.

In addition, the second electrode formation film 1010 is formed by CVD in the semiconductor device manufacturing method of the present embodiment, achieving easy adjustment of the oxygen content of the second electrode formation film 1010 to a desired value.

### Embodiment 2

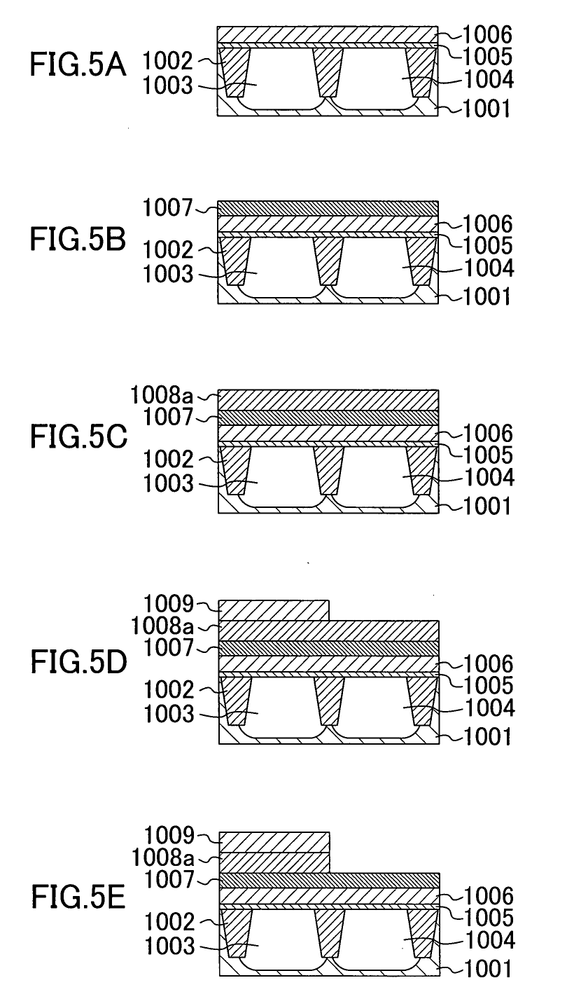

A semiconductor device and a manufacturing method thereof in accordance with Embodiment 2 will be described below with reference to the drawings. FIG. 5 to FIG. 7 are sectional views showing respective steps of the semiconductor device manufacturing method in accordance with Embodiment 2 of the present invention. The semiconductor device manufacturing method in accordance with the present embodiment is a method for manufacturing the semiconductor device of Embodiment 1 by a manner different from that of Embodiment 1. Herein, the same parts as in the semiconductor device manufacturing method of Embodiment I will be described in a simplified manner.

First, as shown in FIG. 5A, the p-type active region 1003, the n-type active region 1004, and the isolation layer 1002 for separating them are formed in the semiconductor substrate 1001. Then, the underlying film 1005 made of, for example, SiO₂ and having a thickness of approximately 1 nm is deposited on the semiconductor substrate 1001 by RTO (Rapid Thermal Oxidation) using an oxygen gas. Any suitable gas other than the oxygen gas may be used. Further, thermal treatment using a heating furnace may be performed. The material of the underlying film 1005 may be SiON, a chemical oxide, or the like. Then, a HfSiO film, for example, having a high dielectric and a thickness of 2.5 nm is deposited by MOCVD (Metal Organic Chemical Vapor Deposition), and the thus deposited HfSiO film is plasma-nitrided to form the gate insulating film 1006 formed of a HfSiON film. The material of the gate insulating film 1006 may be made of HfO₂ or HfSiO, or may be formed of any other suitable Hf-based insulating film containing La. Alternatively, any suitable high dielectric, such as Al₂O₃, ZrO₂, HfO₂, LaO, DyO, ScO, or the like may be used, or SiO₂ or SiON other than high dielectrics may be used according to needs. Rather than MOCVD, another film formation method may be employed, such as CVD (Chemical Vapor Deposition), PVD (Physical Vapor Deposition), or the like.

Next, as shown in FIG. 5B, the first electrode formation film 1007 made of TaC or the like is deposited on the gate insulating film 1006. The film thickness of the first electrode formation film 1007, which can be changed appropriately according to the kind a material of the first electrode formation film 1007 and the peripheral process, is preferably 10 nm or smaller.

Subsequently, as shown in FIG. 5C, the hard mask 1008a made of SiO₂ or the like is formed on the first electrode formation film 1007. Then, a resist 1009 is formed on the hard mask 1008a, and a part of the resist 1009 which is located above the n-type active region 1004 is removed by photolithography, as shown in FIG. 5D.

Thereafter, as shown in FIG. 5E, etching using the resist 1009 remaining above the p-type active region 1003 as a mask is performed to remove a part of the hard mask 1008a which is located above the n-type active region 1004. Then, the resist 1009 is removed by ashing to thus form the hard mask 1008a above the p-type active region 1003 selectively.

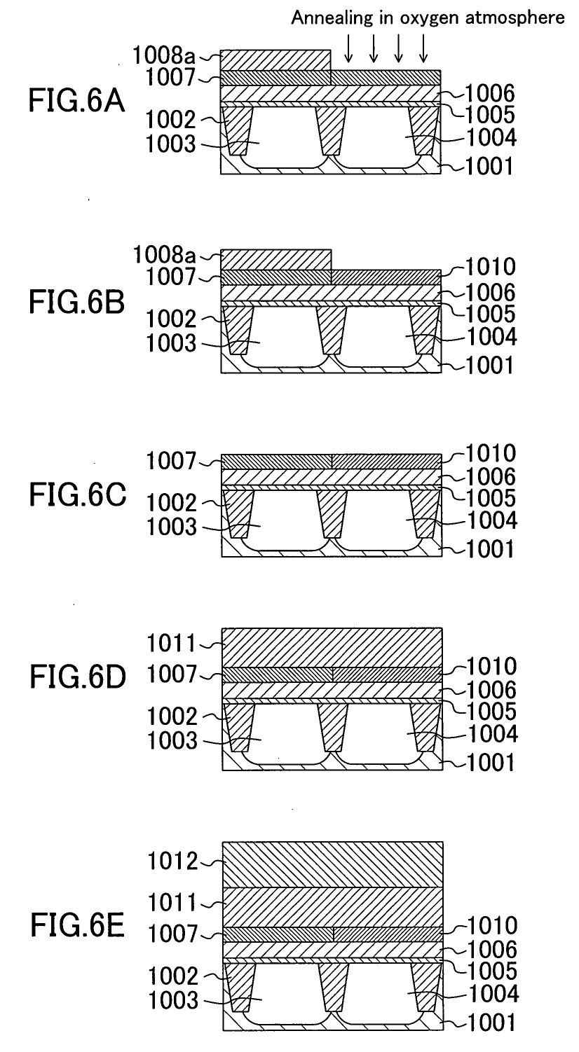

Next, as shown in FIG. 6A, annealing at a high temperature of approximately 800° C. to 1000° C. is performed on the semiconductor substrate 1001 in an oxygen atmosphere. Without the hard mask 1008, a part of the TaC-made first electrode formation film 1007 which is located above the n-type active region 1004 is exposed, thereby being exposed in the oxygen atmosphere in annealing to be oxidized. This forms the second electrode formation film 1010 made of TaCO, as shown in FIG. 6B. Then, as shown in FIG. 6C, the hard mask 1008a is removed with the use of hydrofluoric acid or the like. Thus, the first electrode formation film 1007 and the second electrode formation film 1010 are formed above the p-type active region 1003 and the n-type active region 1004, respectively.

Subsequently, as shown in FIG. 6D, the intermediate film 1011, for example, made of TaN or the like and having a thickness of 5 nm is deposited on the first electrode formation film 1007 and the second electrode formation film 1010. The material of the intermediate film 1011 is not limited to TaN, and any other suitable material can be used. In the semiconductor device manufacturing method of the present embodiment, TaC, which is liable to be oxidized at the interface thereof, is used as the material of the first electrode formation film 1007, and therefore, the intermediate film 1011 is provided as an anti-oxidation film. Accordingly, in the case using a less oxidized material, such as TaN or the like as the material of the first electrode formation film 1007, the intermediate film 1011 may not be provided.

Thereafter, as shown in FIG. 6E, the third electrode formation film 1012, for example, made of polysilicon and having a thickness of 100 nm is deposited on the intermediate film 1011, and then, an impurity is implanted into the third electrode formation film 1012.

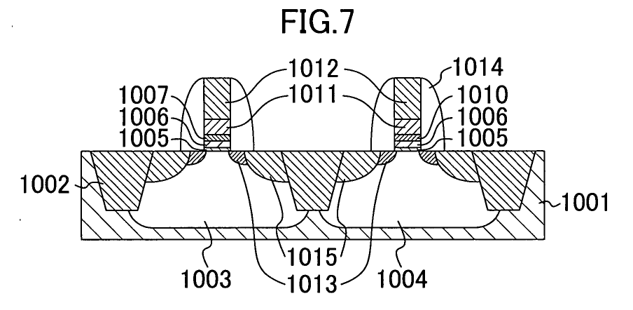

Next, as shown in FIG. 7, the underlying film 1005, the gate insulating film 1006, the first electrode formation film 1007, the second electrode formation film 1010, the intermediate film 1011, and the third electrode formation film 1012 are etched by photolithography and RIE (Reactive Ion Etching) so that parts of each of them are left on the predetermined regions of the p-type active region 1003 and the n-type active region 1004. Then, the extension regions 1013, the sidewalls 1014, the source/drain regions 1015 are formed, and the impurity implanted in the source/drain regions 1015 are activated to thus form the n-type MISFET and the p-type MISFET in the p-type active region 1003 and the n-type active region 1004, respectively. In order to activate the impurity in the source/drain regions 1015, spike annealing at a temperature of, for example, 1050° C. is performed.

By the above method, the n-type MISFET is formed in the p-type active region 1003, wherein the n-type MISFET includes the underlying film 1005, the gate insulating film 1006, the first gate electrode composed of the first electrode formation film 1007, the intermediate film 1011, and the third electrode film 1012, the sidewalls 1014, the source/drain regions 1015, and the extension regions 1013. While in the n-type active region 1004, the p-type MISFET is formed which includes the underlying film 1005, the gate insulating film 1006, the second gate electrode composed of the second electrode formation film 1010, the intermediate film 1011, and the third electrode film 1012, the sidewalls 1014, the source/drain regions 1015, and the extension regions 1013.

One of the significant features in the semiconductor device manufacturing method of the present embodiment lies in that the second electrode formation film 1010 is formed by oxidizing the first electrode formation film 1007 in the step shown in FIG. 6A. This method eliminates the need to remove a metal material (the first electrode formation film 1007) immediately on the gate insulating film 1006 for forming the second electrode formation film 1010, and accordingly, damage to the gate insulating film 1006 and change in film thickness of the gate insulating film 1006, which are caused by dry etching and the like, can be suppressed. As a result, the semiconductor device manufacturing method of the present embodiment attains a highly reliable semiconductor device even when miniaturized.

The semiconductor device manufacturing method of the present embodiment achieves, similarly to that of Embodiment 1, simultaneous formation of an n-type MISFET and a p-type MISFET each including a gate electrode having an appropriate work function, thereby leading to attainment of a semiconductor device, such as a CMIS, having low threshold voltage and capable of high-speed operation with depletion of the gate electrodes suppressed even when miniaturized.

Unlike the semiconductor device manufacturing method of Embodiment 1, only the first electrode formation film 1007 is prepared with the need to deposit the second electrode formation film 1010 eliminated in the semiconductor device manufacturing method of the present embodiment, and accordingly, the semiconductor device shown in FIG. 7 can be manufactured comparatively easily.

### Embodiment 3

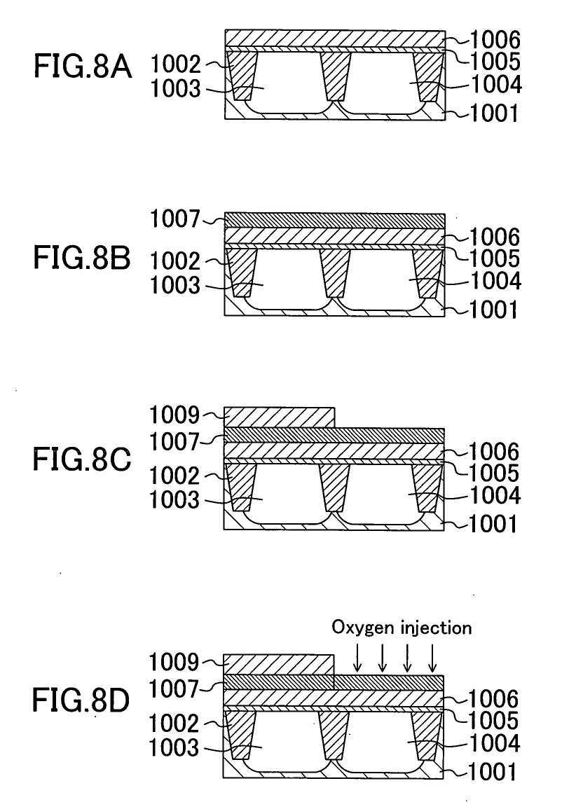

A semiconductor device and a manufacturing method thereof in accordance with Embodiment 3 will be described below with reference to the drawings. FIG. 8 to FIG. 10 are sectional views showing respective steps of the semiconductor device manufacturing method in accordance with Embodiment 3 of the present invention. The semiconductor device manufacturing method in accordance with the present embodiment is a method for manufacturing the semiconductor device of Embodiment 1 by a manner different from those of Embodiment 1 and Embodiment 2. Herein, the same parts as in the semiconductor device manufacturing method of Embodiment 1 will be described in a simplified manner.

First, as shown in FIG. 8A, the p-type active region 1003, the n-type active region 1004, and the isolation layer 1002 for separating them are formed in the semiconductor substrate 1001. Then, the underlying film 1005 made of, for example, SiO₂ and having a thickness of approximately 1 nm is deposited on the semiconductor substrate 1001 by RTO (Rapid Thermal Oxidation) using an oxygen gas. Any suitable gas other than the oxygen gas may be used. Further, thermal treatment using a heating furnace may be performed. The material of the underlying film 1005 may be SiON, a chemical oxide, or the like. Then, a HfSiO film, for example, having a high dielectric and a thickness of 2.5 nm is deposited by MOCVD (Metal Organic Chemical Vapor Deposition), and the thus deposited HfSiO film is plasma-nitrided to form the gate insulating film 1006 formed of a HfSiON film. The gate insulating film 1006 may be made of HfO₂ or HfSiO, or may be formed of any other suitable Hf-based insulating film containing La. Alternatively, any suitable high dielectric, such as Al₂O₃, ZrO₂, HfO₂, LaO, DyO, ScO, or the like may be used, or SiO₂ or SiON other than high dielectrics may be used according to needs. Rather than MOCVD, another film formation method may be employed, such as CVD (Chemical Vapor Deposition), PVD (Physical Vapor Deposition), or the like.

Next, as shown in FIG. 8B, the first electrode formation film 1007 made of TaC or the like is deposited on the gate insulating film 1006. The film thickness of the first electrode formation film 1007, which can be changed appropriately according to the kind of a material of the first electrode formation film 1007 and the peripheral process, is preferably 10 nm or smaller.

Subsequently, the resist 1009 is formed on the first electrode formation film 1007, and then, a part of the resist 1009 which is located above the n-type active region 1004 is removed by photolithography, as shown in FIG. 8C.

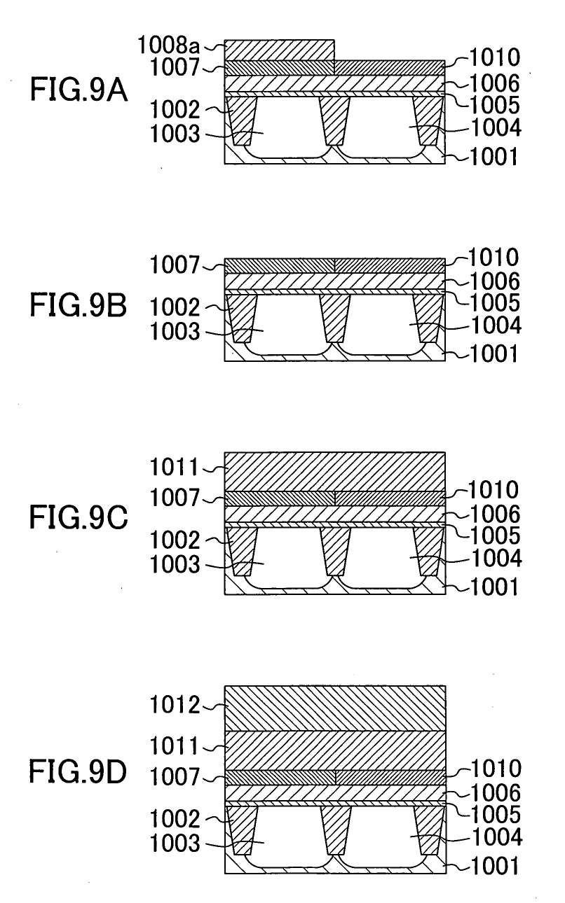

Thereafter, as shown in FIG. 8D, oxygen is injected in the form of ion beam with the use of the resist 1009 located above the p-type active region 1003 as a mask. Without the hard mask 1008, a part of the first electrode formation film 1007 which is located above the n-type active region 1004 is exposed, thereby being subjected to direct exposure by the oxygen ion beam in injection to be oxidized. This forms the second electrode formation film 1010 made of TaCO, as shown in FIG. 9A. Then, as shown in FIG. 9B, the resist 1009 is removed by ashing. As a result, the first electrode formation film 1007 and the second electrode formation film 1010 are formed above the p-type active region 1003 and the n-type active region 1004, respectively.

Next, as shown in FIG. 9C, the intermediate film 1011, for example, made of TaN and having a film thickness of 5 nm is deposited on the first electrode formation film 1007 and the second electrode formation film 1010. The material of the intermediate film 1011 is not limited to TaN, and any other suitable material may be used. In the semiconductor device manufacturing method of the present embodiment, TaC, which is liable to be oxidized at the interface thereof, is used as the material of the first electrode formation film 1007, and therefore, the intermediate film 1011 is provided as an anti-oxidation film. Accordingly, in the case using a less oxidized material, such as TaN or the like as the material of the first electrode formation film 1007, the intermediate film 1011 may not be provided.

Subsequently, as shown in FIG. 9D, the third electrode formation film 1012, for example, made of polysilicon and having a thickness of 100 nm is deposited on the intermediate film 1011, and then, an impurity is implanted into the third electrode formation film 1012.

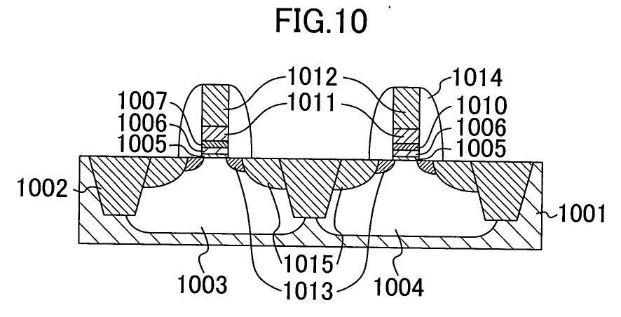

Thereafter, as shown in FIG. 10, the underlying film 1005, the gate insulating film 1006, the first electrode formation film 1007, the second electrode formation film 1010, the intermediate film 1011, and the third electrode formation film 1012 are etched by photolithography and RIE (Reactive Ion Etching) so that parts of each of them are left on the predetermined regions of the p-type active region 1003 and the n-type active region 1004. Then, the extension regions 1013, the sidewalls 1014, the source/drain regions 1015 are formed, and the impurity implanted in the source/drain regions 1015 are activated to thus form the n-type MISFET and the p-type MISFET in the p-type active region 1003 and the n-type active region 1004, respectively. In order to activate the impurity in the source/drain regions 1015, spike annealing at a temperature of, for example, 1050° C. is performed.

By the above method, the n-type MISFET is formed in the p-type active region 1003, wherein the n-type MISFET includes the underlying film 1005, the gate insulating film 1006, the first gate electrode composed of the first electrode formation film 1007, the intermediate film 1011, and the third electrode film 1012, the sidewalls 1014, the source/drain regions 1015, and the extension regions 1013. While in the n-type active region 1004, the p-type MISFET is formed which includes the underlying film 1005, the gate insulating film 1006, the second gate electrode composed of the second electrode formation film 1010, the intermediate film 1011, and the third electrode film 1012, the sidewalls 1014, the source/drain regions 1015, and the extension regions 1013.

One of the significant features of the present embodiment lies in that the second electrode formation film 1010 is formed in such a manner that the first electrode formation film 1007 formed above the n-type active region 1004 is oxidized by injecting an oxygen ion in the step shown in FIG. 8D. This method achieves formation of each gate electrode formation film with no damage to the gate insulating film 1006 invited, similarly to the semiconductor device manufacturing method of Embodiment 2, thereby leading to attainment of a highly reliable semiconductor device even when miniaturized.

Further, the semiconductor device manufacturing method of the present embodiment employs ion injection as an oxidation method to eliminate the need to form the hard mask 1008a for thermal treatment, as in the semiconductor device manufacturing method of Embodiment 2, which means simplification of the semiconductor device manufacturing process.

Polysilicon in which an impurity is implanted is used as the material of the third electrode formation film 1012 in Embodiment 1, Embodiment 2, and Embodiment 3. When a metal, such as tungsten, a meal silicide (titanium silicide, cobalt silicide, or nickel silicide) or the like is used as the material of the third electrode formation film 1012, further high-speed operation of the semiconductor device can be achieved.

Each of the semiconductor device manufacturing methods of the above embodiments is directed to a semiconductor device including the p-type active region 1003 and the n-type active region 1004 in the single semiconductor substrate 1001. Nevertheless, the present invention is not limited thereto and is applicable to a semiconductor device in which a first MISFET and a second MISFET including gate electrodes made of different metal materials are formed in a single semiconductor substrate.

In addition, each of the semiconductor device manufacturing methods of the above embodiments uses a silicon substrate as the semiconductor substrate 1001, but the present invention is not limited thereto. A substrate made of any other suitable material may be used. For example, a SOI (Semiconductor Oxide Insulator) substrate or a substrate made of mixed crystal, such as a GaAs substrate, an InP substrate, or the like may be used.

As described above, the semiconductor device and the manufacturing methods thereof in accordance with the present invention are useful for enhancing the drivability of miniaturized CMISs and the like.

What is claimed is:

1. A semiconductor device, comprising:
a semiconductor substrate;
a p-type active region and an n-type active region which are formed in the semiconductor substrate;
a first MISFET including a first gate insulating film formed on the p-type active region and a first gate electrode formed on the first gate insulating film and including a first electrode formation film containing a metal element; and
a second MISFET including a second gate insulating film formed on the n-type active region and a second gate electrode formed on the second gate insulating film and including a second electrode formation film containing the metal element and having an oxygen content higher than the first electrode formation film.

2. The semiconductor device of claim 1,
wherein the first electrode formation film has a work function smaller than the second electrode formation film.

3. The semiconductor device of claim 2,
wherein the metal element is Ta.

4. The semiconductor device of claim 3,
wherein the second electrode formation film further contains C.

5. The semiconductor device of claim 4,
wherein the first electrode formation film further contains C.

6. The semiconductor device of claim 1,
wherein the first gate insulating film and the second gate insulating film contain at least one selected from the group consisting of HfO₂, HfSiO, and HfSiON.

7. The semiconductor device of claim 1,
wherein the first gate insulating film and the second gate insulating film contain La.

8. The semiconductor device of claim 1,
wherein the first gate insulating film and the second gate insulating film contain Zr.

9. The semiconductor device of claim 1,
wherein an oxygen content of the first electrode formation film is 2% or lower, and the oxygen content of the second electrode formation film is in a range between 10% and 30%, both inclusive.

10. The semiconductor device of claim 1,
wherein the first gate electrode further includes a third electrode formation film formed on or above the first electrode formation film, and
the second gate electrode further includes a fourth electrode formation film formed on or above the second electrode formation film.

11. The semiconductor device of claim 10,
wherein at least one of the third electrode formation film and the fourth electrode formation film contains metal.

12. The semiconductor device of claim 10,
wherein the first gate electrode further includes an intermediate film formed between the first electrode formation film and the third electrode formation film.

13. A method for manufacturing a semiconductor device including a semiconductor substrate, a p-type active region, an n-type active region, a first MISFET including a first gate insulating film and a first gate electrode, and a second MISFET including a second gate insulating film and a second gate electrode, the method comprising the steps of:
(a) forming a gate insulating film on the semiconductor substrate after the p-type active region and the n-type active region are formed in the semiconductor substrate;
(b) forming a first electrode formation film on a part of the gate insulating film which is located on the p-type active region, the first electrode formation film containing a metal element;
(c) forming a second electrode formation film on a part of the gate insulating film which is located on the n-type active region, the second electrode formation film containing the metal element and having an oxygen content higher than the first electrode formation film; and
(d) removing a part of the first electrode formation film, a part of the second electrode formation film, and a part of the gate insulating film to form on the p-type active region the first gate electrode provided on the first gate insulating film and including the first electrode formation film and form on the n-type active region the second gate electrode provided on the second gate insulating film and including the second electrode formation film.

14. The semiconductor device manufacturing method of claim 13,
wherein the step (b) includes the steps of:
(b1) forming the first electrode formation film on each of the parts of the gate insulating film which are located on the p-type active region and the n-type active region; and
(b2) removing the first electrode formation film with the part located on the p-type active region left, and
the step (c) includes the steps of:
(c1) forming the second electrode formation film on the first electrode formation film and the gate insulating film; and
(c2) removing the second electrode formation film with the part located on the n-type active region left.

15. The semiconductor device manufacturing method of claim 13,
wherein the step (b) includes the step of forming the first electrode formation film on each of the parts of the gate insulating film which are located on the p-type active region and the n-type active region, and
the step (c) includes the step of oxidizing a part of the first electrode formation film which is located on the n-type active region to form the second electrode formation film containing the metal element and having an oxygen content higher than the first electrode formation film.

16. The semiconductor device manufacturing method of claim 15,
wherein in the step (c), the part of the first electrode formation film which is located on the n-type active region is oxidized by performing thermal treatment under an oxygen atmosphere.

17. The semiconductor device manufacturing method of claim 15,
wherein in the step (c), the part of the first electrode formation film which is located on the n-type active region is oxidized by injecting an oxygen ion.

18. The semiconductor device manufacturing method of claim 13, wherein the metal element is Ta.
